(19) United States
(12) Patent Application Publication
(10) Pub. No.: US 2025/0359004 A1
(43) Pub. Date: Nov. 20, 2025

(54) CFET SRAM WITH BUTT CONNECTION ON ACTIVE AREA

(71) Applicant: Taiwan Semiconductor Manufacturing Co., Ltd., Hsinchu (TW)

(72) Inventors: Cheng-Yin WANG, Hsinchu (TW); Szuya LIAO, Hsinchu (TW); Jui-Chen HUANG, Hsinchu (TW)

(73) Assignee: Taiwan Semiconductor Manufacturing Co., Ltd., Hsinchu (TW)

(21) Appl. No.: 19/285,641

(22) Filed: Jul. 30, 2025

Related U.S. Application Data
(63) Continuation of application No. 18/163,746, filed on Feb. 2, 2023.
(60) Provisional application No. 63/335,137, filed on Apr. 26, 2022.
(60) Provisional application No. 63/418,360, filed on Oct. 21, 2022.

(51) Int. Cl. H10B 10/00

(52) U.S. Cl. CPC H10B 10/125

(57) ABSTRACT

An integrated circuit includes a plurality of SRAM cells. Each SRAM cell includes a first inverter having a first N-type transistor and a first P-type transistor stacked vertically in a first active region. The SRAM cell includes a second inverter cross-coupled with the first inverter and including a second N-type transistor and a second P-type transistor stacked vertically in a second active region. The SRAM cell includes a butt contact electrically connecting an output of the first inverter to an input of the second inverter. The butt contact is at least partially within a first active region.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of semiconductor substrate.

Complementary field effect transistors (CFETs) may be utilized to increase the density of transistors in an integrated circuit. A CFET may include an N-type transistor and a P-type transistor stacked vertically. The gate electrodes of the N-type and P-type transistors may be electrically shorted together.

Static random access memory (SRAM) cells may be formed utilizing CFETs. While this can reduce the layout area of the term cell with respect to non-CFET layouts, each SRAM cell may nevertheless still take up a relatively large amount of area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of an SRAM cell, in according with some embodiments.

FIG. 1B is a layout of an SRAM cell, in accordance with some embodiments.

FIGS. 1C and 1D are cross-sectional views of half of an SRAM bit-cell formed in accordance with the layout 102 of FIG. 1B, in accordance with some embodiments.

FIGS. 2A-5B are cross-sectional views of half of an SRAM bit-cell, in accordance with some embodiments.

FIG. 6A is a layout of an SRAM cell, in accordance with some embodiments.

FIG. 6B is a cross-sectional view of half of an SRAM bit-cell formed in accordance with the layout of FIG. 6A, in accordance with some embodiments.

FIGS. 7-9 are cross-sectional views of half of an SRAM bit-cell, in accordance with some embodiments.

FIG. 10 is a perspective view of an SRAM bit-cell, in accordance with some embodiments.

FIG. 11 is a schematic diagram of an SRAM array, in accordance with some embodiments.

FIG. 12 is a flow diagram of a method for forming an integrated circuit, in accordance with some embodiments.

### DETAILED DESCRIPTION

In the following description, many thicknesses and materials are described for various layers and structures within an integrated circuit die. Specific dimensions and materials are given by way of example for various embodiments. Those of skill in the art will recognize, in light of the present disclosure, that other dimensions and materials can be used in many cases without departing from the scope of the present disclosure.

The following disclosure provides many different embodiments, or examples, for implementing different features of the described subject matter. Specific examples of components and arrangements are described below to simplify the present description. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “one embodiment” or “an embodiment” means that a particular feature, structure or characteristic described in connection with the embodiment is included in at least some embodiments. Thus, the appearances of the phrases “in one embodiment”, “in an embodiment”, or “in some embodiments” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure provide an integrated circuit with CFET based SRAM cells having reduced area consumption. Each SRAM cell includes a first inverter formed of a first CFET and a second inverter formed of a second CFET. Butt contacts that connect the input of the first inverter to the output of the second inverter, and that connect the input of the second inverter to the output of the first inverter are formed at least partially overlapping the active regions associated with the CFETs. The butt contacts may be formed through back end processes or front end processes. Because the butt contacts are positioned at least partially within the active regions, the layout of the SRAM cell can be compressed with respect to traditional SRAM layouts. The result is integrated circuits with denser arrays of SRAM cells. This can lead to larger numbers of SRAM cells in an array or the inclusion of additional integrated circuit components within the integrated circuits.

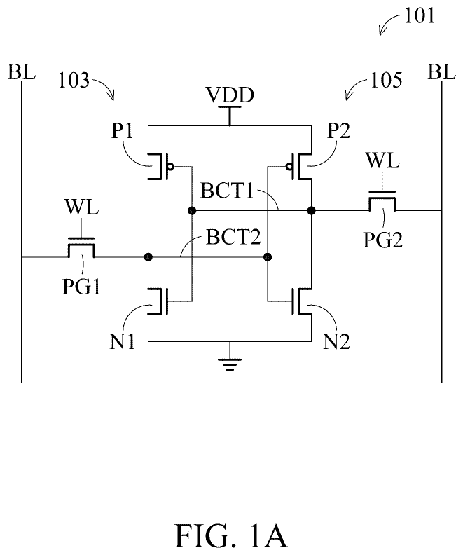

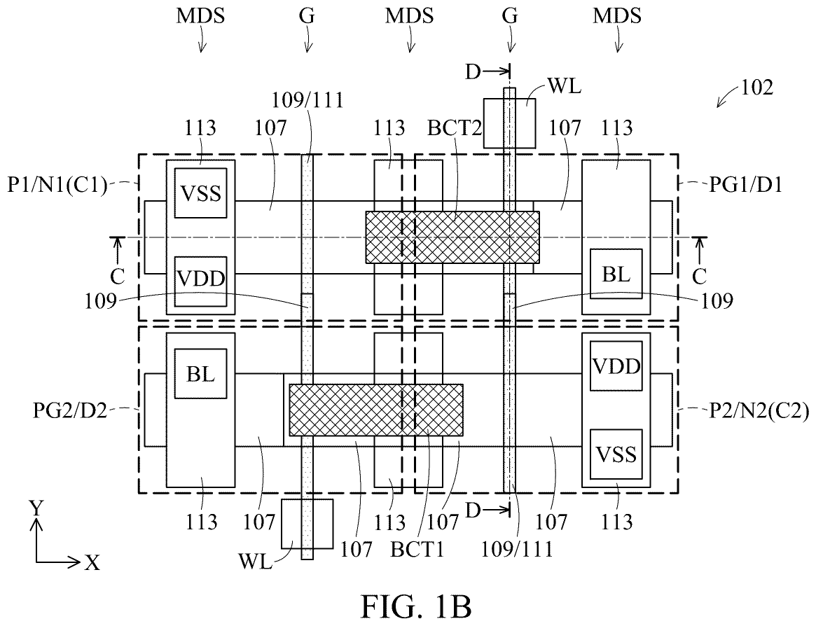

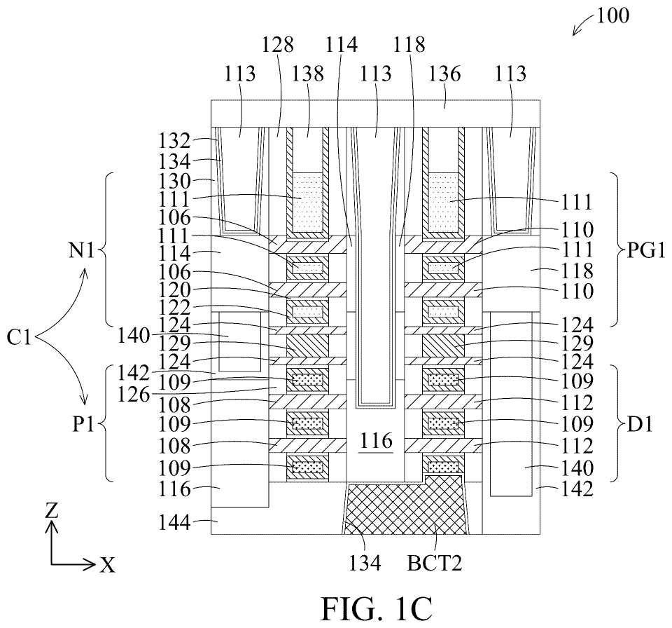

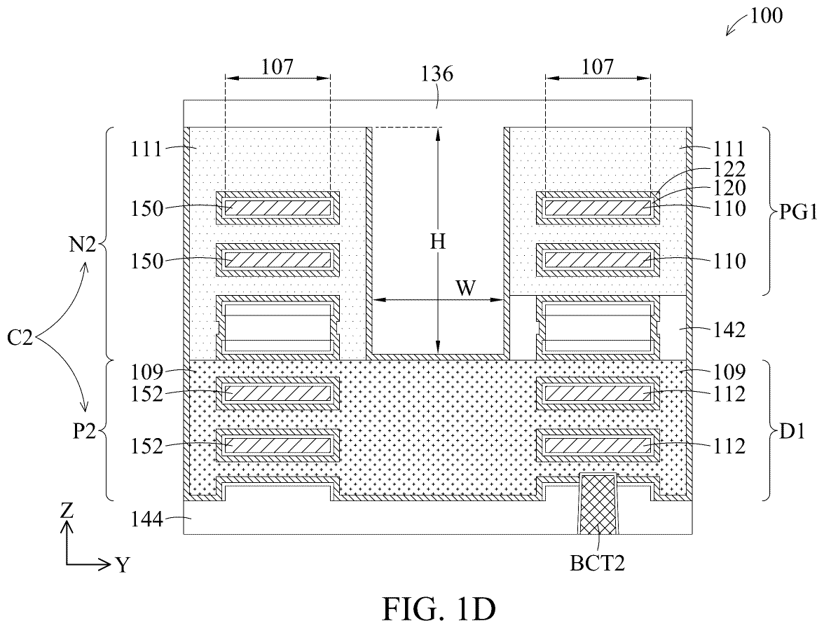

FIG. 1A is a schematic diagram of an SRAM cell 101, in accordance with some embodiments. The SRAM cell 101 is a six transistor SRAM cell. As will be set forth in more detail below, the layout of the SRAM cell 101 provides reduced area consumption for SRAM cells. Further details regarding the layout and cross-sectional structures of the SRAM cell 101 are shown in relation to FIGS. 1B-1D.

The SRAM cell 101 includes a first inverter 103 and a second inverter 105. The first inverter 103 includes a first P-type transistor P1 and a first N-type transistor N1. The gate terminals of the transistors P1 and N1 are coupled together. The drain terminals of the transistors P1 and N1 are coupled together. The source terminal of the transistor P1 is coupled to the supply voltage VDD. The source terminal of the transistor N1 is coupled to ground. The transistors P1 and N1 collectively correspond to a CFET transistor C1.

The second inverter 105 includes a P-type transistor P2 and an N-type transistor N2. The gate terminals of the transistors P2 and N2 are coupled together. The drain terminals of the transistors P2 and N2 are coupled together. The source terminal of the transistor P2 is coupled to the supply voltage VDD. The source terminal of the transistor N2 is coupled to ground (VSS). The transistors P2 and N2 collectively correspond to a CFET transistor C2.

The SRAM cell 101 includes a first pass gate transistor PG1 and a second pass gate transistor PG2. The gate terminals of the transistors P1 and P2 are coupled to word lines WL. The drain of the transistor PG1 is coupled to the drain terminals of the transistors P1 and N1, which collectively correspond to the output of the inverter 103. The source terminal of the transistor PG1 is coupled to a bit line BL. The drain terminal of the transistor PG2 is coupled to the drain terminals of the transistors P2 and N2, which collectively correspond to the output of the inverter 105. The source terminal of the transistor PG2 is coupled to a bit line BL. In the example of FIG. 1A, the transistors PG1 and PG2 are N-type transistors, though in other examples the transistors PG1 and PG2 may be P-type transistors. The transistors P1 and P2 may be termed pull up transistors. The transistors N1 and N2 may be termed pull down transistors.

As set forth above, the output of the inverter 103 is coupled to the input of the inverter 105. The output of the inverter 105 is coupled to the input of the inverter 103. The connector that couples the output of the inverter 105 to the input of the inverter 103 is a first butt contact BCT1. The connection that couples the output of the inverter 103 to the input of the inverter 105 is a second butt contact BCT2.

The formation of butt contacts of an SRAM cell can result in relatively large layout areas of an SRAM cell. This is because, the butt contacts are generally offset from the active area of the transistors of the SRAM cell. However, the butt contacts BCT1 and BCT2 of the SRAM cell 101 avoid drawbacks of traditional solutions. In particular, the butt contacts BCT1 and BCT2 are formed overlapping or entirely within the active area of the SRAM cells. The result is that a significantly reduced amount of area is consumed by the SRAM cell 101 with respect to other SRAM cells. This will be made clearer in relation to FIGS. 1B-1D.

FIG. 1B is a layout 102 of the SRAM cell 101 of FIG. 1A, in accordance with some embodiments. The layout corresponds to a top view that illustrates the relative locations of various areas and materials of the SRAM cell 101 in terms of X and Y axes. The X and Y axes are mutually orthogonal horizontal axes. The layout 102 does not illustrate all of the materials and structures utilized in forming an integrated circuit that includes the SRAM cell 101. Instead, the layout 102 illustrates the position of the active areas 107, the gate metals 109/111, the source/drain metals 113, and the butt contacts BCT1 and BCT2.

The active regions 107 correspond to locations of semiconductor material that makes up the channel regions and the source/drain regions of the transistors of the SRAM cell 101. In some embodiments, the portions of the active area extending between adjacent source/drain metals 113 include a plurality of semiconductor nanostructures that make up the channel regions of the transistors of the SRAM cell 101. The active regions 107 may correspond to regions of semiconductor material separated from each other by shallow trench isolations or other structures.

As used herein, the term “active region” refers to a set of X-Y coordinates associated with a layout of active semiconductor material. A butt contact BCT is considered overlapping the active region if at least a portion of the butt contact BCT shares X-Y coordinates of the active region, even if the butt contact is above or below actual semiconductor material of the active region. A butt contact BCT is considered to be entirely within the active region if the X-Y coordinates of the butt contact are entirely within the X-Y coordinates of the active region.

Each active region 107 can correspond to a location of a semiconductor fin from which the source, drain, and channel regions of a plurality of transistors are formed. Each active region 107 can include the source/drain and channel regions of a large number of transistors. In some embodiments, active regions 107 are separated from each other by inactive regions. The first inverter 103, the first pass gate transistor PG1, and the first dummy transistor D1 of a large number of SRAM cells 101 can be formed in a first active region 107. The second inverter 105, the second pass gate transistor PG2, and the second dummy transistor D2 of the SRAM cells 101 can be formed in a second adjacent active region 107 spaced apart from the first active region 107. Forming the butt contacts BCT as described herein, enables adjacent active regions 107 to be placed closer together, thereby shrinking the overall area of SRAM cells 101 and enabling more SRAM cells 101 to be formed in the integrated circuit.

The labels MDS refer to source/drain metals 113. In particular, MDS indicates lines that extend through source/drain metals 113 of the transistors of the SRAM cell 101. The label G indicates lines that extend through gate metals 109/111 of the transistors of the SRAM cell 111. As will be described in more detail below, because the SRAM cell 101 includes CFETs each corresponding to a P-type transistor and an N-type transistor stacked in the vertical direction, the gate metal 109 of the P-type transistors and the gate metal 111 of the N-type transistors overlap each other in the X-Y plane. In particular, the gate metal 109 of the P-type transistors is positioned directly below the gate metal 111 of the N-type transistors, except at particular locations at which the gate metal 111 is broken or cut.

The location corresponding to the transistors P1 and N1 (C1) is in the upper left of the layout 102. The location corresponding to the transistors P2 and N2 (C2) is in the lower right of the layout 102. The location of the pass gate transistor PG1 and a dummy transistor D1 is in the upper right of the layout 102. The location of the pass gate transistor PG to and a dummy transistor D2 is in the lower left of the layout 102. The transistors P1, N1, and PG1 share a common drain region. The transistors P2, N2, and PG2 share a common drain region.

The boxes VSS correspond to locations at which a ground contact connects to the portions of the source/drain metal 113 corresponding to the source regions of the N-type transistors N1 and N2. The boxes VDD correspond to locations at which high supply voltage contacts connect to the portions of the source/drain metal 113 corresponding to the source regions of the P-type transistors P1 and P2. The boxes WL correspond to locations at which word line contacts connect to the gate metals 109/111. The boxes BL correspond to locations at which bit line, contacts connect to the portions of the source/drain metal 113 corresponding to the source regions of the pass gate transistors PG1 and PG2.

The layout 102 indicates the locations of butt contacts BCT1 and BCT2. The butt contacts BCT1 and BCT2 overlie the active regions 107. In the example of FIG. 1B, BCT1 and BCT2 do not extend laterally outside of the active regions 107. Portions of BCT1 and BCT2 may be within the active region 107 while other portions of BCT1 and BCT2 are outside the active region 107.

BCT2 connects the source/drain metal 113 associated with the drain terminals of the transistors P1/N1/PG1 (output of the inverter 103) to a portion of the gate metal 109 that is electrically connected to the gate terminals of the transistors P2 and N2 (input of the inverter 105). This electrical connection is more apparent with respect to the cross-sectional views of FIGS. 1C and 1D.

BCT1 connects the source/drain metal 113 associated with the drain terminals of the transistors P2/N2/PG2 (output of the inverter 105) to a portion of the gate metal 109 that is electrically connected to the gate terminals of the transistors P1 and N1 (input of the inverter 103).

The location of the butt contacts BCT1 and BCT2 within the layout 102 provides various benefits. Because the butt contacts are positioned only overlying the active regions 107, the area of the layout 102 is significantly reduced with respect to traditional SRAM layouts in which butt contacts are positioned entirely outside the active region, thereby significantly enlarging the layouts of traditional SRAM cells in the Y direction. The result is integrated circuits that can include denser arrays of SRAM cells or that can use integrated circuit area for other purposes.

FIG. 1C is a cross-sectional view of an integrated circuit 100 formed in accordance with the layout 102 of the SRAM cell 101 of FIG. 1B, in accordance with some embodiments. The view of FIG. 1C corresponds to cut lines C in the layout 102 of FIG. 1B. The view of FIG. 1C illustrates the CFET C1 including transistors N1 and P1. The view of FIG. 1C also illustrates the transistor PG1 and the dummy transistor D1. The transistor N1 is stacked above the transistor P1. The transistor PG1 is stacked above the dummy transistor D1.

The transistors of the SRAM cell 101 (including N1, P1, and PG1 shown in FIG. 1C) may correspond to gate all around transistors. The gate all around transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the gate all around structure. Furthermore, the gate all around transistors may each include a plurality of semiconductor nanostructures corresponding to channel regions of the transistors. The semiconductor nanostructures may include nanosheets, nanowires, or other types of nanostructures. The gate all around transistors may also be termed nanostructure transistors.

The transistor N1 includes a plurality of semiconductor nanostructures 106. The semiconductor nanostructures 106 are stacked in the vertical direction or Z-direction. In the example of FIG. 1C, there are two stacked semiconductor nanostructures 106. However, in practice, there may be more than two stacked nanostructures 106 without departing from the scope of the present disclosure. Furthermore, in some embodiments there may be only a single semiconductor nanostructure 106. The semiconductor nanostructures 106 correspond to channel regions of the transistor N1. The semiconductor nanostructures 106 may be nanosheets, nanowires, or other types of nanostructures.

The transistor P1 includes a plurality of semiconductor nanostructures 108. The semiconductor nanostructures 108 are stacked in the vertical direction or Z-direction. In the example of FIG. 1C, there are two stacked semiconductor nanostructures 108. However, in practice, there may be more than two stacked nanostructures 108 or only a single nanostructure 108 without departing from the scope of the present disclosure. The semiconductor nanostructures 108 correspond to channel regions of the transistor P1. The semiconductor nanostructures 108 may be nanosheets, nanowires, or other types of nanostructures. In FIG. 1C the number of semiconductor nanostructures 106 is the same as the number of semiconductor nanostructures 108. However, in some embodiments the number of nanostructures 106 may be different than the number of semiconductor nanostructures 108.

The semiconductor nanostructures 106 and 108 may include Si, SiGe, or other semiconductor materials. In a non-limiting example described herein, the semiconductor nanostructures 106 are silicon. The vertical thickness of the semiconductor nanostructures 106 can be between 2 nm and 5 nm. The semiconductor nanostructures 106 may be separated from each other in the vertical direction by 4 nm to 10 nm. Other thicknesses and materials can be utilized for the semiconductor nanostructures 106 without departing from the scope of the present disclosure. The semiconductor nanostructures 108 may have a same material and dimensions as the semiconductor nanostructures 106 or a different semiconductor material from the semiconductor nanostructures 106.

The transistors N1 and P1 include a gate dielectric. The gate dielectric includes an interfacial gate dielectric layer 120 and a high-K gate dielectric layer 122. The interfacial gate dielectric layer 120 is a low-K gate dielectric layer. The interfacial gate dielectric layer is in contact with the semiconductor nanostructures 106 and 108. The high-K gate dielectric layer 122 is in contact with the low-K gate dielectric layer. The interfacial gate dielectric layer 120 is positioned between the semiconductor nanostructures 106 and the high-K gate dielectric layer 122 and between the semiconductor nanostructures 108 and the high-K gate dielectric layer 122.

The interfacial gate dielectric layer 120 can include a dielectric material such as silicon oxide, silicon nitride, or other suitable dielectric materials. The interfacial dielectric layer 120 can include a comparatively low-K dielectric with respect to high-K dielectric such as hafnium oxide or other high-K dielectric materials that may be used in gate dielectrics of transistors. The interfacial dielectric layer 120 can include a native oxide layer that grows on surfaces of the semiconductor nanostructures 106 and 108. The interfacial dielectric layer 120 have a thickness between 0.4 nm and 2 nm. Other materials, configurations, and thicknesses can be utilized for the interfacial dielectric layer 120 without departing from the scope of the present disclosure.

The high-K gate dielectric layer includes one or more layers of a dielectric material, such as HfO2, HfSiO, HfSION, HfTaO, HfTIO, HfZrO, zirconium oxide, aluminum oxide, titanium oxide, hafnium dioxide-alumina (HfO2-Al2O3) alloy, other suitable high-k dielectric materials, and/or combinations thereof. The thickness of the high-k dielectric is in a range from about 1 nm to about 3 nm. Other thicknesses, deposition processes, and materials can be utilized for the high-K gate dielectric layer without departing from the scope of the present disclosure. The high-K gate dielectric layer may include a first layer that includes HfO2 with dipole doping including La and Mg, and a second layer including a higher-K ZrO layer with crystallization.

The transistor N1 includes a gate metal 111. The gate metal 111 surrounds the semiconductor nanostructures 106. The gate metal 111 is in contact with the high-K gate dielectric layer 122. The gate metal 111 corresponds to a gate electrode of the transistor N1. In an example in which the transistor N1 is an N-type transistor, the gate metal 111 can include a material that results in a desired work function with the semiconductor nanostructures 106. In one example, the gate metal 111 includes titanium aluminum, titanium, aluminum, tungsten, copper, gold, or other conductive materials.

FIG. 1C illustrates a single gate metal 111. However, in practice, the gate electrode of the transistor N1 can include multiple metal layers. For example, the gate metal 111 can include one or more liner layers or adhesive layers such as tantalum, tantalum nitride, titanium nitride, or other materials. The gate metal 111 can include a gate fill material that fills the remaining volume between the semiconductor nanostructures 106 after the one or more liner layers have been deposited. Various materials, combinations of materials, and configurations may be utilized for the gate metal 111 without departing from the scope of the present disclosure.

The transistor P1 includes a gate metal 109. The gate metal 109 surrounds the semiconductor nanostructures 108. The gate metal 109 is in contact with the high-K gate dielectric layer 122. The gate metal 109 corresponds to a gate electrode of the transistor P1. In an example in which the transistor P1 is a P-type transistor, the gate metal 109 can include a material that results in a desired work function with the semiconductor nanostructures 108. In one example, the gate metal 109 includes titanium nitride, titanium, aluminum, tungsten, copper, gold, or other conductive materials.

FIG. 1C illustrates a single gate metal 109. However, in practice, the gate electrode from the transistor P1 can include multiple metal layers that wrap around the semiconductor nanostructures 108. For example, the gate metal 111 can include one or more liner layers or adhesive layers such as tantalum, tantalum nitride, titanium nitride, or other materials. The gate metal 109 can include a gate fill material that fills the remaining volume between the semiconductor nanostructures 108 after the one or more liner layers have been deposited. Various materials, combinations of materials, and configurations may be utilized for the gate metal 109 without departing from the scope of the present disclosure.

The transistor N1 includes source/drain regions 114. The source/drain regions 114 are in contact with each of the semiconductor nanostructures 106. Each semiconductor nanostructure 106 extends in the X-direction between the source/drain regions 114. The source/drain regions 114 include a semiconductor material.

The transistor P1 includes source/drain regions 116. The source/drain regions 116 are in contact with each of the semiconductor nanostructures 108. Each semiconductor nanostructure 107 extends in the X-direction between the source/drain regions 116. The source/drain regions 116 include a semiconductor material.

The source/drain regions 114 can be doped with N-type dopants species. The N-type dopant species can include P, As, or other N-type dopant species. The source/drain regions 116 can be doped with P-type dopant species. The P-type dopant species can include B or other P-type dopant species. The doping can be performed in-situ during an epitaxial growth process of the source/drain regions 116. The source/drain regions 114 and 116 can include other materials and structures without departing from the scope of the present disclosure.

As used herein, the term “source/drain region” may refer to a source region or a drain region individually or collectively dependent upon the context. Accordingly, one of the source/drain regions 114 may be a source region while the other source/drain region 114 is a drain region, or vice versa. In one embodiment, the left source/drain region 114 is a source region of the transistor N1 and the right source/drain region 114 is a drain region of the transistor N1. The left source/drain region 116 is a source region of the transistor P1 and the right source/drain region is a drain region of the transistor P1.

The transistors N1 and P1 each include inner spacers 126. The inner spacers 126 can include silicon oxide, silicon nitride, silicon oxynitride, silicon carbonitride, silicon oxycarbonitride, fluorine-doped silicate glass (FSG), a low-K dielectric material or other dielectric materials without departing from the scope of the present disclosure. In one example, the inner spacers 126 include silicon oxycarbonitride.

The inner spacers 126 of the transistor N1 physically separate the gate metal 111 from the source/drain regions 114. This prevents short circuits between the gate metal 111 and the source/drain regions 114. The inner spacers 126 of the transistor P1 physically separate the gate metal 109 from the source/drain regions 116. This prevents short circuits between the gate metal 109 and the source/drain regions 116.

The transistor PG1 may be substantially identical to the transistor N1. The transistor PG1 includes semiconductor nanostructures 110 and source/drain regions 118. The semiconductor nanostructures 110 extend in the X direction between the source/drain regions 118. The gate dielectric layers 120 and 122 surround the semiconductor nanostructures 110. The gate metal 111 surrounds the semiconductor nanostructures 110 with the gate dielectric layers 120 and 122 positioned between the semiconductor nanostructures 110 and the gate metal 111. In some embodiments, the right source/drain region 118 is a source region of the transistor PG1. The left source/drain region 118 is a drain region of the transistor PG1. In practice, the right source/drain region 114 and the left source/drain region 118 are integral with each other. The transistor PG1 may have the same structures and materials as described in relation to the transistor N1 in embodiments in which PG1 and N1 are both N-type transistors.

The dummy transistor D1 is positioned below the pass gate transistor PG1. The dummy transistor D1 has semiconductor nanostructures 112 surrounded by the gate dielectric layers 120 and 122 and the gate metal 109. In many respects, the dummy transistor D1 is substantially identical to the transistor P1. However, the dummy transistor D1 is a functional as a transistor because the semiconductor nanostructures 112 do not connect on the right side to a source/drain region. Instead, dielectric layers 140 and 142 take up the entirety of the location at which a source/drain region will be formed if the dummy transistor D1 was functional.

The dummy transistor D1 nevertheless serves a useful purpose in the SRAM cell 101. In particular, though not apparent in FIG. 1C, the gate metal 109 extends unbroken in the Y direction to surround the semiconductor nanostructures of the transistor P2. Accordingly, the gate electrode of the dummy transistor D1 is electrically shorted with the gate electrode of the transistor P2, as can be seen in FIG. 1D.

A left source/drain metal 113 is electrically connected to the left source/drain region 114 (source region, in some embodiments) of the transistor N1. Though not shown in FIG. 1C, the contact VSS connects to the left source/drain metal 113. A central source/drain metal 113 electrically connects to the right source/drain region 114 of the transistor N1, the left source/drain region 118 of the transistor PG1, and the right source/drain region 116 of the transistor P1. In the example of FIG. 1C. The central source/drain region 113 connects to the drain region of each of the transistors N1, P1, and PG1. A right source/drain region 113 is electrically connected to the right source/drain region 118 (source terminal, in some embodiments) of the transistor PG1. The source/drain metal 113 can include titanium, aluminum, nickel, tungsten, tantalum, or other suitable conductive materials.

In some embodiments, a silicide may be positioned between the various source/drain regions and the source/drain metals 113. Conductive layers 132 and 134 may be positioned in contact with the source/drain metals 113. The conductive layers one and 134 can include titanium nitride, tantalum nitride, titanium, tantalum, or other suitable conductive materials.

FIG. 1C illustrates the butt contact BCT2. The butt contact BCT2 electrically connects the gate metal 109 of the dummy transistor D1 to the right source/drain region 116 of the transistor P1. Because the gate metal 109 of the dummy transistor D1 is electrically shorted to the gate metal 109 of the transistor P2 and to the gate metal 111 of the transistor N2, and because the drain terminals of the transistors N1, P1, and PG1 are shorted together, the butt contact BCT2 electrically connects the input of the inverter 105 with the output of the inverter 103. Accordingly, the gate metal 109 of the dummy transistor D1 acts as a bridge between the drain regions of N1, P1, and PG1 and the gate electrodes of N2 and P2.

As can be seen in FIG. 1C, the butt contact BCT2 is formed underlying the semiconductor drain regions of the transistors N1, P1, and PG1 and underlying the semiconductor nanostructures 110 and 112 of the transistors PG1 and D1. Accordingly, the butt contact is formed underlying an active region 107 associated with the transistors N1, P1, PG1, and D1. As described previously, this greatly reduces the layout of the SRAM cell 101 with respect to traditional SRAM cells.

The butt contact BCT2 can be formed as part of the backside processing of the integrated circuit 100. In particular, after front end processing of the transistors of the SRAM cell 101 has been performed, the integrated circuit 100 can be flipped for backend processing. The backend processing can include replacing semiconductor substrate materials with dielectric materials, such as the dielectric material 144. The dielectric materials can be patterned to expose source/drain regions and gate metals 109 at various locations. Butt contacts BCT1 and BCT2 can then be formed at the exposed locations. While FIG. 1C illustrates backside butt contacts, in practice, the butt contacts can be formed on the front side above the transistors N1, P1, PG1, and D1.

FIG. 1C illustrates the transistors N1, PG1, P1, D1 and the butt contact BCT2. However, the butt contact BCT1 and the transistors N2, P2, PG2, and D2 are substantially identical to the transistors N1, PG1, P1, D1 and the butt contact BCT2, aside from some differences in orientation. Accordingly, the principles, structures and materials illustrated in FIG. 1C can be applied to the butt contact BCT1 and the transistors N2, P2, PG2, and D2.

The butt contact BCT2 can include one or more of aluminum, titanium, tantalum, titanium nitride, tantalum nitride, copper, gold, or other suitable conductive materials. The butt contact BCT2 can include a conductive layer 134 lining the butt contact BCT2.

The integrated circuit 100 includes sidewall spacers 128. The sidewall spacers 128 are positioned adjacent to the uppermost portion of the gate metal 111 and electrically isolate the gate metal 111 from the source/drain metals 113. The sidewall spacers 128 may include one or more of silicon oxide, silicon nitride, silicon oxynitride, silicon carbonitride, silicon oxycarbonitride, fluorine-doped silicate glass (FSG), a low-K dielectric material or other dielectric materials. Other thicknesses and materials can be utilized for the sidewall spacers 128 without departing from the scope of the present disclosure.

The integrated circuit 100 may include a dielectric layer 144. The dielectric layer 144 may be positioned in contact with the bottom and sidewalls of the source/drain regions 116. The dielectric layer 144 may include silicon oxide, silicon nitride, silicon oxynitride, silicon carbonitride, silicon oxycarbonitride, fluorine-doped silicate glass (FSG), a low-K dielectric material or other dielectric materials.

The integrated circuit 100 includes hybrid nanostructures between the semiconductor nanostructures 106 and the semiconductor nanostructures 108. More particularly, the hybrid nanostructure is positioned directly between the lowest semiconductor nanostructure 106 and the highest semiconductor nanostructure 108 and between the lowest nanostructure 110 and the highest nanostructure 112. The hybrid nanostructure may be a hybrid nanosheet, a hybrid nanowire, or another type of nanostructure. The hybrid nanostructure may include upper and lower semiconductor layers 124 and a dielectric layer 129 between the upper and lower semiconductor layers 124. Various structures and compositions can be utilized for the hybrid nanostructure without departing from the scope of the present disclosure. The dielectric layer 129 may include silicon oxide, silicon nitride, silicon oxynitride, silicon carbonitride, silicon oxycarbonitride, fluorine-doped silicate glass (FSG), a low-K dielectric material or other dielectric materials.

The integrated circuit 100 may include a dielectric layer 130 between the gate spacer structures 128 and the source/drain metals 113. The dielectric layer 130 can include silicon oxide, silicon nitride, silicon oxynitride, silicon carbonitride, silicon oxycarbonitride, fluorine-doped silicate glass (FSG), a low-K dielectric material or other dielectric materials.

The integrated circuit 100 may include a dielectric layer 138 on top of the highest portions of the gate metal 111. The dielectric layer 138 can include silicon oxide, silicon nitride, silicon oxynitride, silicon carbonitride, silicon oxycarbonitride, fluorine-doped silicate glass (FSG), a low-K dielectric material or other dielectric materials.

The integrated circuit 100 may include a dielectric layer 136 on top of the source/drain metals 113. The dielectric layer 138 can include silicon oxide, silicon nitride, silicon oxynitride, silicon carbonitride, silicon oxycarbonitride, fluorine-doped silicate glass (FSG), a low-K dielectric material or other dielectric materials.

The integrated circuit 100 can include a dielectric layer 140 and a dielectric liner 142 between the left source/drain regions 114 and 116. The dielectric layers 140 and the dielectric liner 142 may include different compositions of silicon oxide, silicon nitride, silicon oxynitride, silicon carbonitride, silicon oxycarbonitride, fluorine-doped silicate glass (FSG), a low-K dielectric material or other dielectric materials.

FIG. 1D is a cross-sectional view of the integrated circuit 100 of FIG. 1C, taken at a location corresponding to cut lines D in the layout 102 of FIG. 1B, in accordance with some embodiments. FIG. 1D illustrates portions of the transistors PG1 and D1. In particular, FIG. 1D illustrates the gate metal 111 surrounding the semiconductor nanostructures 110 of the transistor PG1. FIG. 1D also illustrates the gate metal 109 surrounding the semiconductor nanostructures 112 of the dummy transistor D1. The gate metal 109 and the gate metal 111 are isolated from each other at the transistors PG1 and D1 by the hybrid nanostructures and the dielectric layer 142.

FIG. 1D also illustrates the height H of the top side cut into the gate metal 111. Particular, the height H substantially corresponds to the height of the gate metal 111 of the transistor N2 above the gate metal 109 of the transistor P2. The height H may be between 20 nm and 40 nm, though other dimensions can be utilized without departing from the scope of the present disclosure. FIG. 1D also illustrates the width W of the top side cut into the gate metal 111. The width W may correspond substantially to the distance between the gate metal 111 of the transistor N2 and the gate metal 111 of the transistor PG1. The width W may be between 40 nm and 60 nm, though other dimensions can be utilized without departing from the scope of the present disclosure. FIG. 1D also illustrates how the combination of the gate metal 111 of the transistor N2 and the gate metal 109 of the transistors P2 and D1 form an L-shape, due to the isolation between the gate metal 111 of the transistor PG1 and the gate metal 109 of the transistor D1.

FIG. 1D illustrates that the top of the gate metal 111 of the transistor PG1 extends to a same vertical level as the top of the gate metal 111 of the transistor N2. However, the bottom of the gate metal 111 of the transistor PG1 does not extend as low as the bottom of the gate metal 111 of the transistor N2. The reason for this is that gate metals 111 and 109 of the transistors N2 and P2 are intended to be shorted together as the output of the inverter 105, while the gate metal 111 of PG1 and the gate metal 109 of the transistor D1 are not intended to be shorted together. Accordingly, the dielectric layer 142 is formed between the gate metals 109 and 111 of the transistors PG1 and D1, thereby ensuring that the bottom of the gate metal 111 of the transistor PG1 does not extend to contact the top of the gate metal 109 of the transistor D1.

FIG. 1D illustrates the transistors N2 and P2, corresponding to a CFET C2. The transistor N2 includes semiconductor nanostructures 150 and is substantially identical to the transistor N1. The gate metal 111 surrounds the semiconductor nanostructures 150, with the gate dielectric layers 120 and 122 between the gate metal 111 and the semiconductor nanostructures 150. The transistor P2 includes semiconductor nanostructures 152 and the substantially identical to the transistor P1. The gate metal 109 surrounds the semiconductor nanostructures 152, with the gate dielectric layers 120 and 122 positioned between the gate metal 109 and the semiconductor nanostructures 152.

The gate metals 109 and 111 are in direct contact with each other at the transistors P2 and N2. Accordingly, the gate electrode of the transistor N2 is shorted with the gate electrode of the transistor P2, corresponding to the input of the inverter 105.

The but contact BCT2 is electrically connected to the gate metal 109. The gate metal 109 extends as a bridge between the dummy transistor D1 and the transistor P2. Accordingly, the input of the inverter 105 is coupled to the drain terminals of the transistors N1, P1, and PG1. The gate metal 111 of the transistor PG1 is not shorted with the gate metal 111 of the transistor N2 this is because the gate metal 111 is removed between the transistors N2 and PG1. A dielectric layer 136 extends above and between the gate metal 111 of the transistors N2 and PG1.

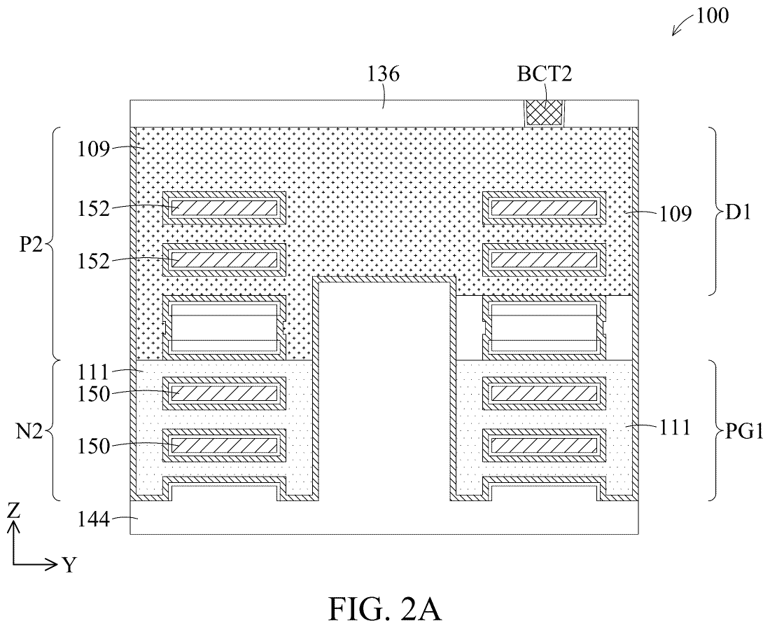

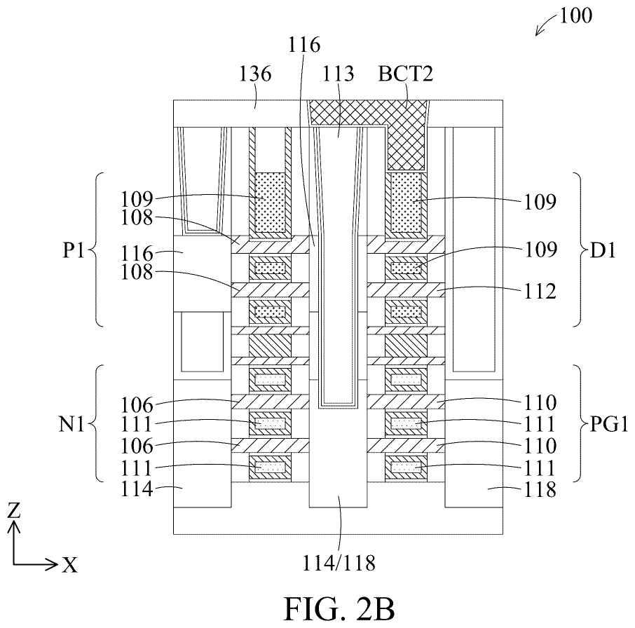

FIGS. 2A and 2B are cross-sectional views of an integrated circuit 100, in accordance with some embodiments. FIG. 2A corresponds to the view of FIG. 1D. FIG. 2B corresponds to the view of FIG. 1C. With reference to both FIGS. 2A and 2B, the integrated circuit 100 is substantially similar to the integrated circuit 100 of FIGS. 1C and 1D, except that the P-type transistors are formed above the N-type transistors. In particular, P1 is formed above N1, P2 is formed above N2, and D1 is formed above PG1. Furthermore, the butt contact BCT2 is a top side contact positioned on top of the central source/drain metal 113 and the gate metal 109 of the dummy transistor D1. The dielectric layer 136 has been patterned to expose the central source/drain metal 113 and the gate metal 109 of the transistor D1. The butt contact BCT2 has been formed on the top surfaces of the central source/drain metal 113 and the gate metal 109 of the transistor D1. The gate metal 109 acts as a bridge extending between the transistors D1 and P2. The gate metal 111 is coupled from the backside so that the gate metal 111 of N2 is not shorted to the gate metal 111 of PG1. The backside dielectric layer 144 extends in the gap between the gate metals 111 of N2 and PG1.

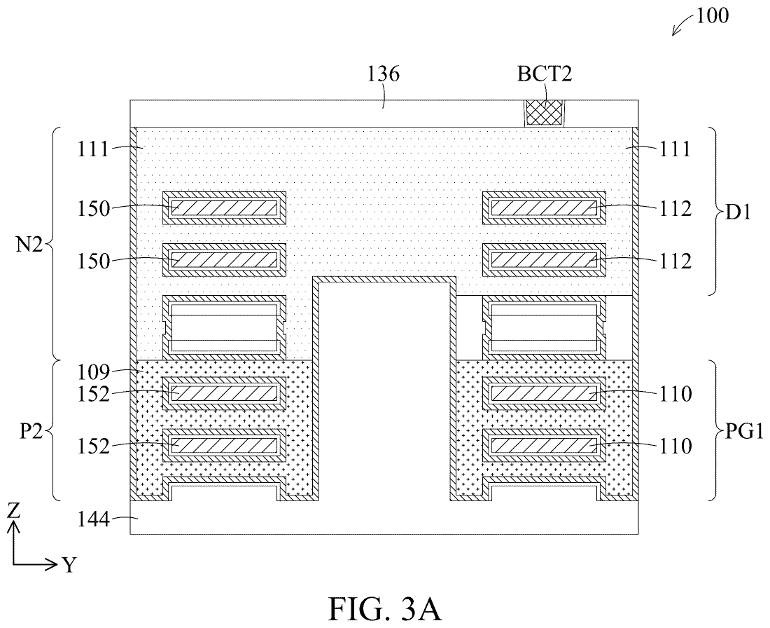

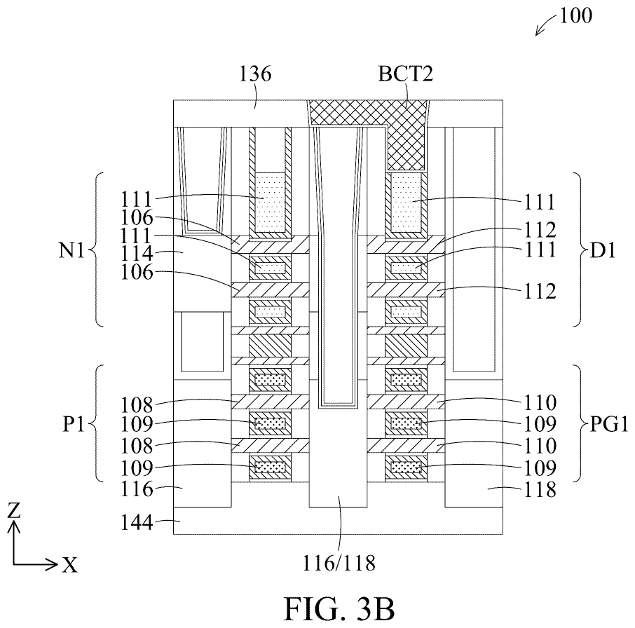

FIGS. 3A and 3B are cross-sectional views of an integrated circuit 100, in accordance with some embodiments. FIG. 3A corresponds to the view of FIG. 1D. FIG. 3B corresponds to the view of FIG. 1C. With reference to both FIGS. 3A and 3B, the integrated circuit 100 is substantially similar to the integrated circuit 100 of FIGS. 1C and 1D, except that the pass gate transistor PG1 is a P-type transistor. Accordingly, D1 is an N-type transistor and is formed above PG1. The gate metal 111 acts as the bridge between D1 and N2, shorting the gate of D1 with the gates of N2 and P2. The butt contact BCT2 is a top side contact positioned on top of the central source/drain metal 113 and the gate metal 111 of the dummy transistor D1. The dielectric layer 136 has been patterned to expose the central source/drain metal 113 and the gate metal 109 of the transistor D1. The butt contact BCT2 has been formed on the top surfaces of the central source/drain metal 113 and the gate metal 111 of the transistor D1. The gate metal 111 acts as a bridge extending between the transistors D1 and N2. The gate metal 109 is cut from the backside so that the gate metal 109 of P2 is not shorted to the gate metal 109 of PG1. The backside dielectric layer 144 extends in the gap between the gate metals 109 of P2 and PG1.

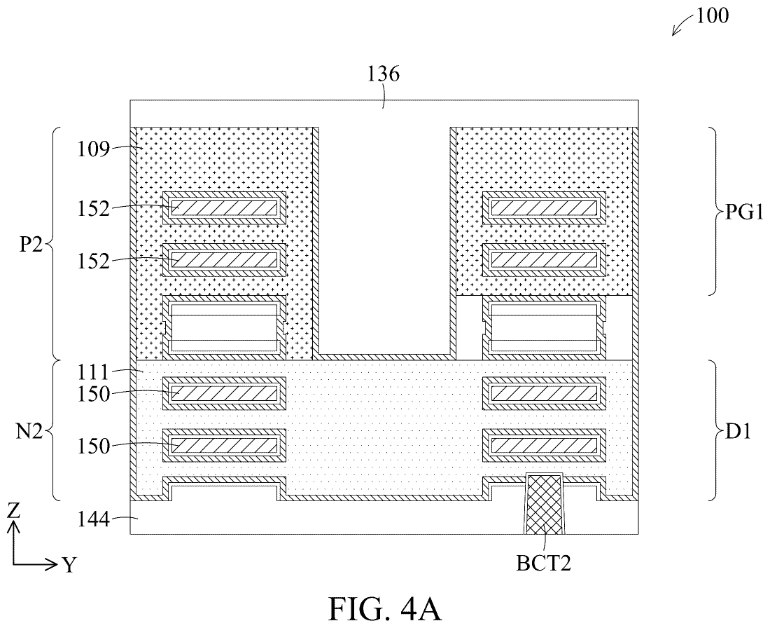

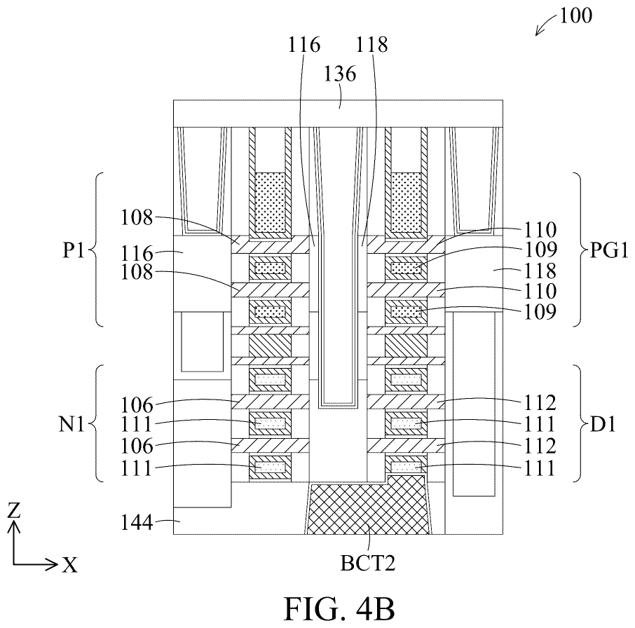

FIGS. 4A and 4B are cross-sectional views of an integrated circuit 100, in accordance with some embodiments. FIG. 4A corresponds to the view of FIG. 1D. FIG. 4B corresponds to the view of FIG. 1C. With reference to both FIGS. 4A and 4B, the integrated circuit 100 is substantially similar to the integrated circuit 100 of FIGS. 1C and 1D, except that the pass gate transistor PG1 is a P-type transistor and the P-type transistors are formed above the N-type transistors. Accordingly, D1 is an N-type transistor and is formed below PG1. The gate metal 111 acts as the bridge between D1 and N2, shorting the gate of D1 with the gates of N2 and P2. The butt contact BCT2 is a back side contact.

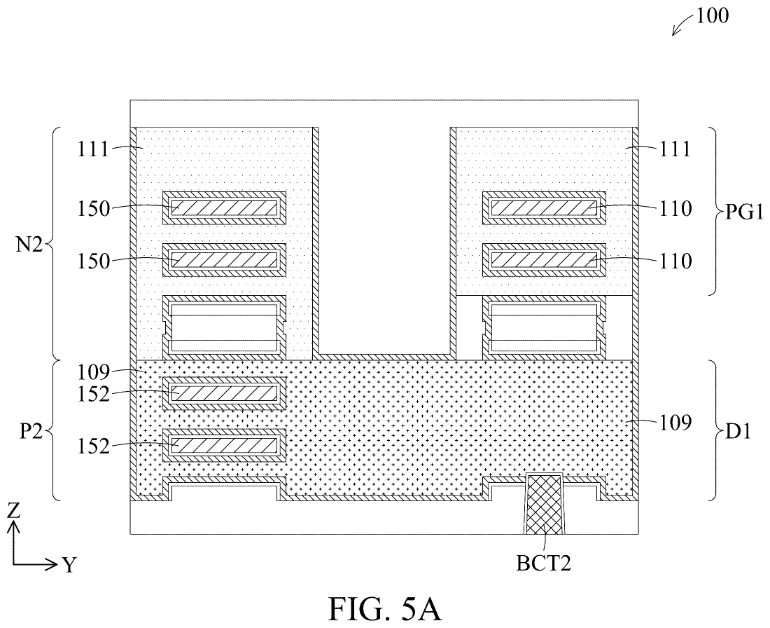

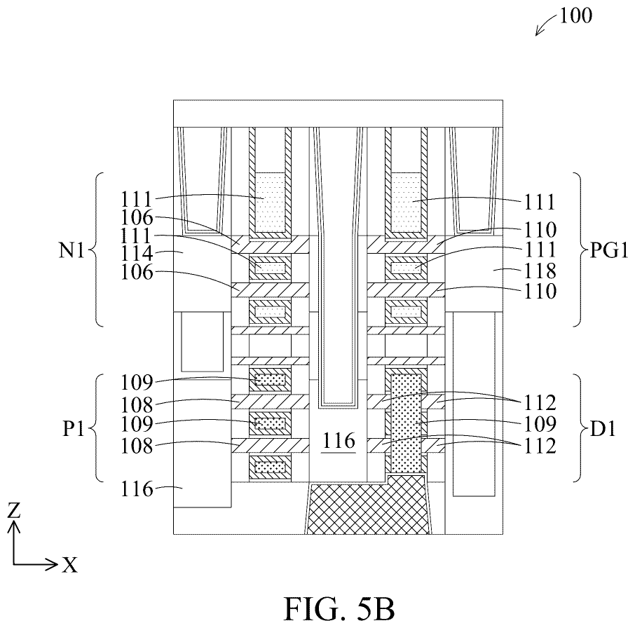

FIGS. 5A and 5B are cross-sectional views of an integrated circuit 100, in accordance with some embodiments. FIG. 5A corresponds to the view of FIG. 1D. FIG. 5B corresponds to the view of FIG. 1C. With reference to both FIGS. 5A and 5B, the integrated circuit 100 is substantially similar to the integrated circuit 100 of FIGS. 1C and ID, except that the semiconductor nanostructures 112 of the dummy transistor D1 have been substantially removed prior to deposition of the gate metal 109. In the view of FIG. 5B, the gate metal 109 is positioned in a gap or trench between cut portions of the semiconductor nanostructures 112. In FIG. 5A, the remnant of the semiconductor nanostructures 112 are not visible. Removal of portions of the semiconductor nanostructures 112 and subsequent filling of the gap with the gate metal 109 results in a stronger electrical connection of the butt contact BCT2 the gate metals 109 and 111 of the transistors P2 and N2.

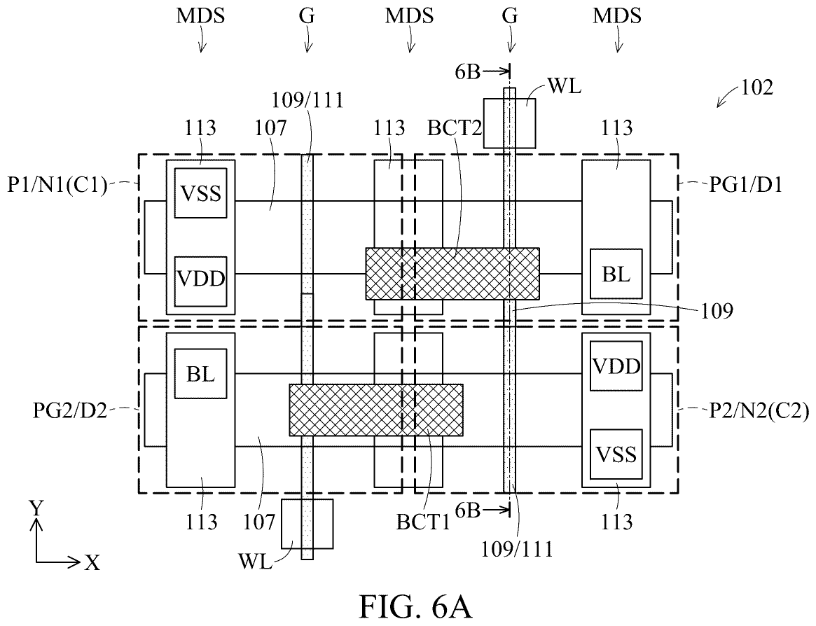

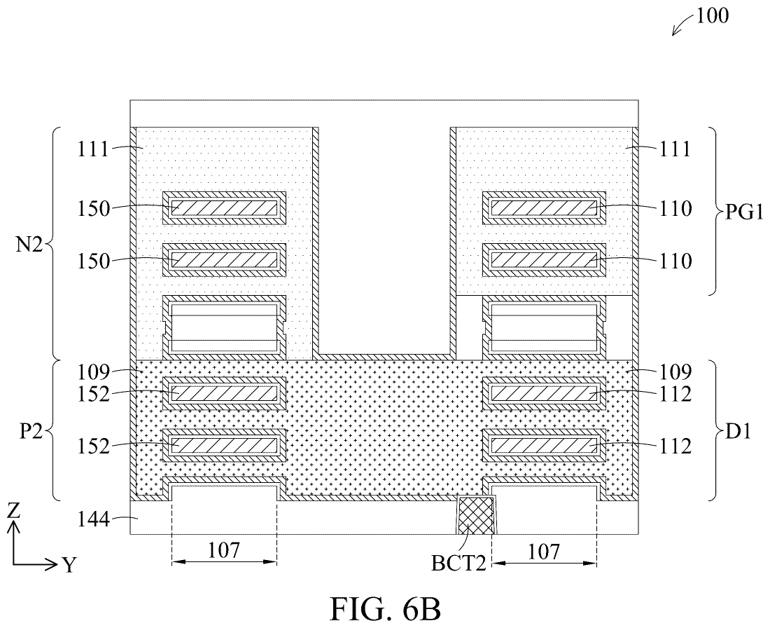

FIG. 6A is a layout 102 of an SRAM cell 101, in accordance with some embodiments. The layout 102 of FIG. 6A is substantially similar to the layout 102 of FIG. 1B, except that the butt contact BCT2 overlaps the edge of the active region 107 of the transistors P1, N1, PG1, and D1. This does not increase the overall area of the layout of the SRAM cell 101 because BCT2 does not extend in the Y direction past the source/drain metal 113 corresponding to the joint drain of P1, N1, and PG1. In FIG. 6A, BCT1 is substantially in the same position as in FIG. 1B. However, in some embodiments, BCT1 can also overlie the edge of the active region 107 of the transistors P1, N1, PG1, and D1. In some embodiments, BCT1 can overlie the edge of the active area 107 while BCT2 does not overlie the edge of the active area 107.

FIG. 6B is cross-sectional view of an integrated circuit 100 formed in accordance with the layout 102 of FIG. 6A, in accordance with some embodiments. The integrated circuit 100 of FIG. 6B is substantially similar to the integrated circuit 100 of FIG. 1D, except that the butt contact overlaps the edge of the active area 107 in the Y direction. In particular, a first portion of the butt contact BCT2 is formed directly below the semiconductor nanostructures 112 and 110, while a second portion of the butt contact BCT2 is not directly below the semiconductor nanostructures 110 and 112. In some embodiments, it may be beneficial to position the butt contact BCT2 overlapping the edge of the active area because a shallower opening can be formed in the dielectric layer 144 than in cases in which BCT2 is entirely within the active region.

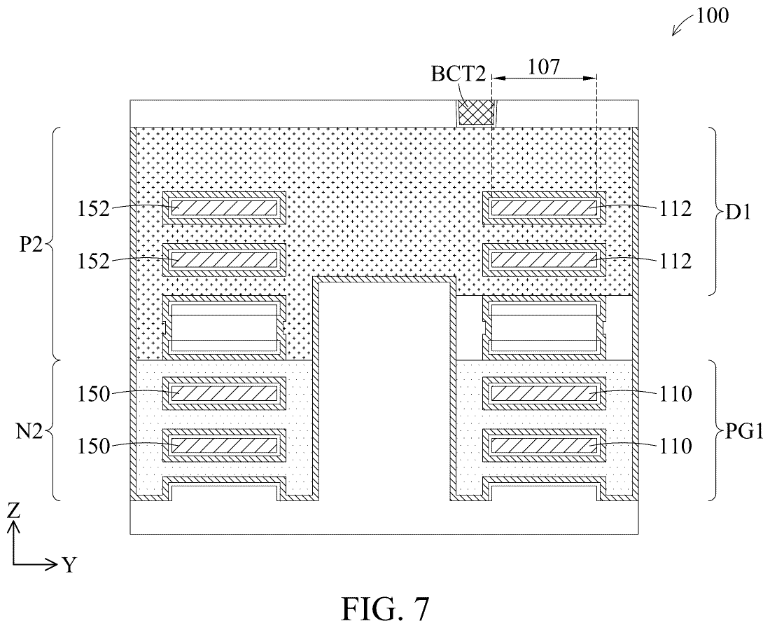

FIG. 7 is a cross-sectional view of an integrated circuit 100, in accordance with some embodiments. The integrated circuit 100 of FIG. 7 is substantially similar to the integrated circuit 100 of FIG. 2A, except that the butt contact BCT2 overlaps the edge of the active region 107.

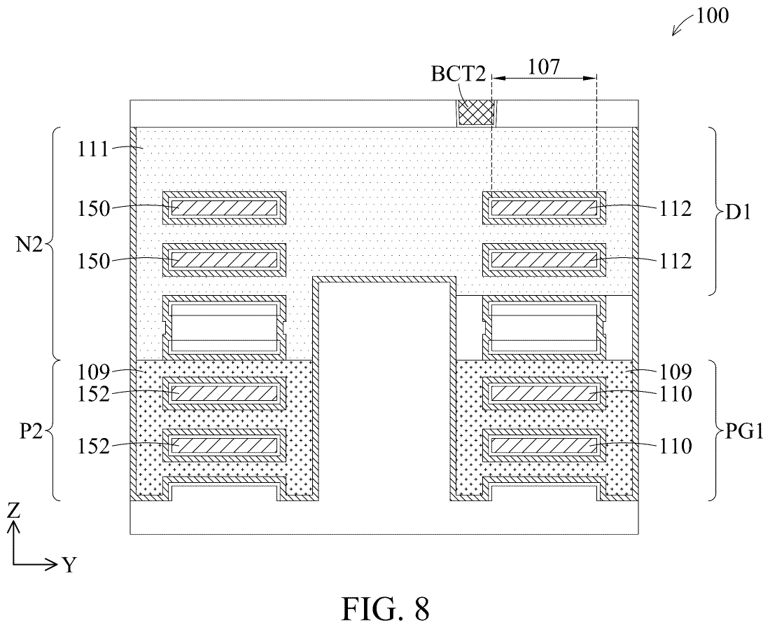

FIG. 8 is a cross-sectional view of an integrated circuit 100, in accordance with some embodiments. The integrated circuit 100 of FIG. 8 is substantially similar to the integrated circuit 100 of FIG. 3A, except that the butt contact BCT2 overlaps the edge of the active region 107.

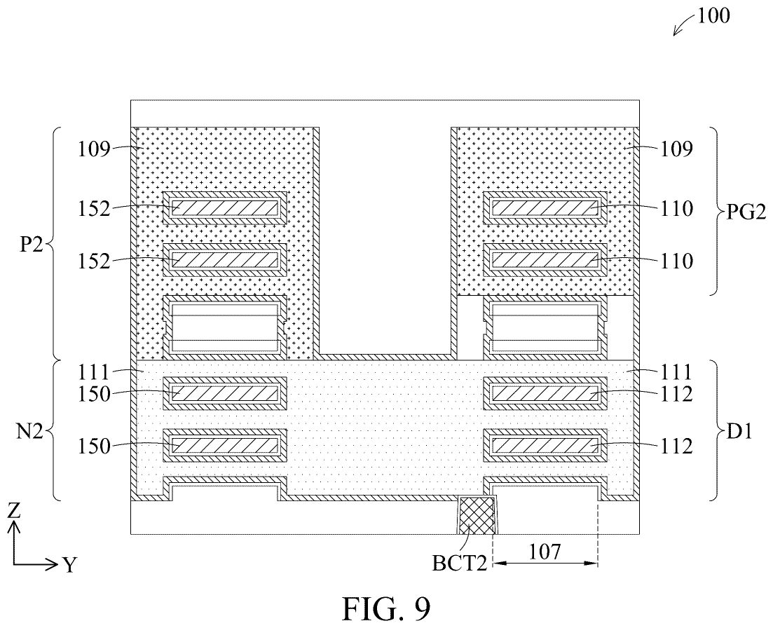

FIG. 9 is a cross-sectional view of an integrated circuit 100, in accordance with some embodiments. The integrated circuit 100 of FIG. 9 is substantially similar to the integrated circuit 100 of FIG. 4A, except that the butt contact BCT2 overlaps the edge of the active region 107.

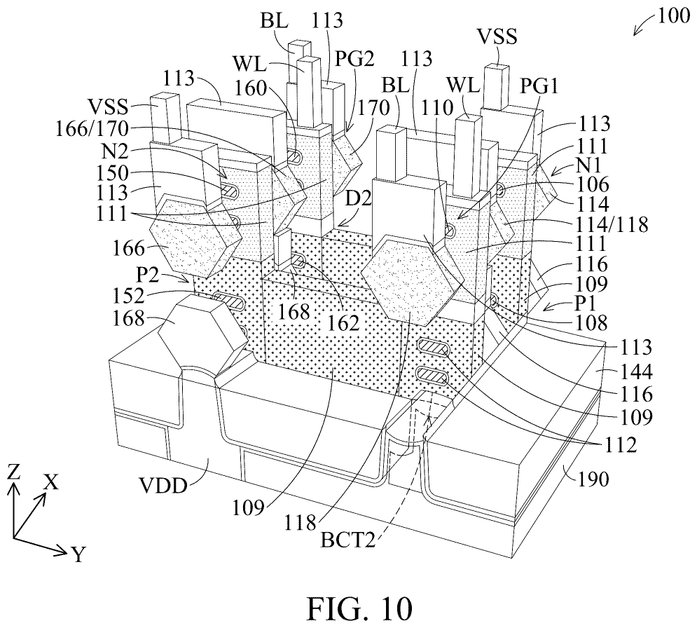

FIG. 10 is a perspective view of an integrated circuit 100 formed in accordance with the layout 102 of FIG. 1B, in accordance with some embodiments. The view of FIG. 10 does not illustrate some dielectric layers. The view of FIG. 10 illustrates the positions of the transistors N1, P1, N2, P2, PG1, D1, PG2, and D2. The view of FIG. 10 also illustrates source/drain regions 168 of the transistor P2, source/drain regions 166 of the transistor N2, the source/drain regions 170 of the transistor PG2. FIG. 10 also illustrates the semiconductor nanostructures 160 of the transistor PG2 and the semiconductor nanostructures 162 of the dummy transistor D2. FIG. 10 illustrates some of the various contacts WL, BL, VDD, VSS and BCT2. BCT1 and one of the backside VDD contacts are not visible due to being obscured by other features of the integrated circuit 100. FIG. 10 illustrates a dielectric layer 190 below the dielectric layer 144. Various other configurations of an integrated circuit 100 can be utilized without departing from the scope of the present disclosure.

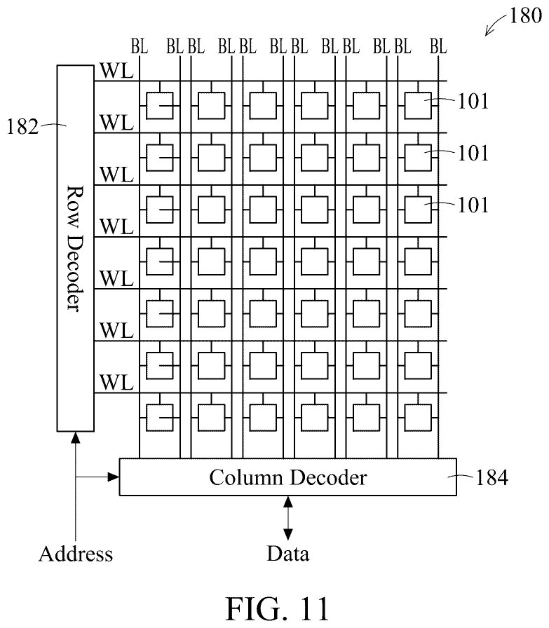

FIG. 11 is a schematic diagram of an SRAM array 180, in accordance with some embodiments. The SRAM array 180 includes a plurality of SRAM cells 101 arranged in rows and columns. Each SRAM cell 101 correspond to the SRAM cell 101 can include layouts, configurations, and structures shown and described in relation to FIGS. 1A-10. The SRAM array 180 can include a row decoder 182 and a column decoder 184. Addressing information can be provided to the row decoder 182 and the column decoder 184 to read data from or to write data to the SRAM cells 101. In particular, data can be written and read via the column decoder 184. The SRAM array 180 can be formed in an integrated circuit 100 as described in relation to FIGS. 1A-10.

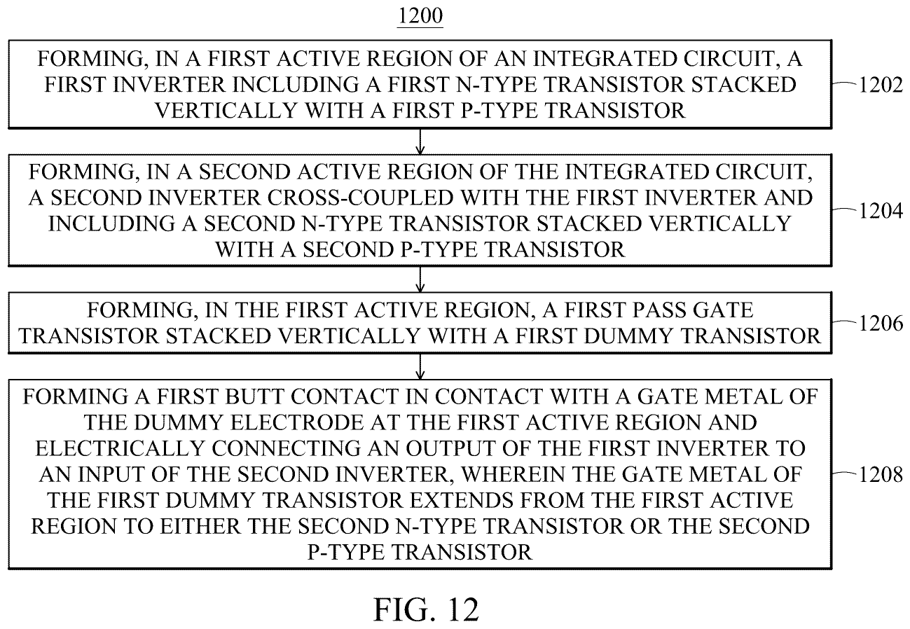

FIG. 12 is a flow diagram of a method 1200 for forming an integrated circuit, in accordance with some embodiments. The method 1200 can utilize components, structures, and processes described in relation to FIGS. 1A-11. At 1202, the method 1200 includes forming, in a first active region of an integrated circuit, a first inverter including a first N-type transistor stacked vertically with a first P-type transistor. One example of an active region is the active region 107 of FIG. 1B. One example of an integrated circuit is the integrated circuit 100 of FIG. 1C. One example of a first inverter is the first inverter 103 of FIG. 1A. One example of a first N-type transistor is the N-type transistor N1 of FIG. 1C. One example of a first P-type transistor is the P-type transistor P2 of FIG. 1C.

At 1204, the method 1200 includes forming, in a second active region of the integrated circuit, a second inverter cross-coupled with the first inverter and including a second N-type transistor stacked vertically with a second P-type transistor. One example of a second active region is the lower active region 107 of FIG. 1B. One example of a second inverter is the second inverter 103 of FIG. 1A. One example of a second N-type transistor is the N-type transistor N2 of FIG. 1D. One example of a second P-type transistor is the P-type transistor P2 of FIG. 1D.

At 1206, the method 1200 includes forming, in the first active region, a first pass gate transistor stacked vertically with a first dummy transistor. One example of a first pass gate transistor is the pass gate transistor PG1 of FIG. 1C. One example of a first dummy transistor is the dummy transistor D1 of FIG. 1C.

At 1208, the method 1200 includes forming a first butt contact in contact with a gate metal of the dummy transistor at the first active region and electrically connecting an output of the first inverter to an input of the second inverter. The gate metal of the first dummy transistor extends from the first active region to either the second N-type transistor or the second P-type transistor. One example of a first butt contact is the butt contact BCT2 of FIG. 1B.

Embodiments of the present disclosure provide an integrated circuit with CFET based SRAM cells having reduced area consumption. Each SRAM cell includes a first inverter formed of a first CFET and a second inverter formed of a second CFET. Butt contacts that connect the input of the first inverter to the output of the second inverter, and that connect the input of the second inverter to the output of the first inverter are formed at least partially overlapping the active regions associated with the CFETs. The butt contacts may be formed through back end processes or front end processes. Because the butt contacts are positioned at least partially within the active regions, the layout of the SRAM cell can be compressed with respect to traditional SRAM layouts. The result is integrated circuits with denser arrays of SRAM cells. This can lead to larger numbers of SRAM cells in an array or the inclusion of additional integrated circuit components within the integrated circuits.

In some embodiments, an integrated circuit includes a first inverter including a first N-type transistor and a first P-type transistor stacked vertically and a second inverter including a second N-type transistor and a second P-type transistor stacked vertically. The integrated circuit includes a first butt contact electrically connecting an output of the first inverter to an input of the second inverter, wherein the first butt contact is at least partially within a first active region associated with the first inverter.

In some embodiments, an integrated circuit includes a first N-type transistor including a gate electrode and a plurality of semiconductor nanostructures corresponding to channel regions of the first N-type transistor. The integrated circuit includes a first P-type transistor stacked vertically with the first N-type transistor and including a gate electrode and a plurality of semiconductor nanostructures corresponding to channel regions of the first P-type transistor. The integrated circuit includes a first pass gate transistor including a gate electrode and a plurality of semiconductor nanostructures corresponding to channel regions of the first pass gate transistor, wherein a source/drain region of the first pass gate transistor, a source/drain region of the first N-type transistor, and source/drain region of the first P-type transistor are all electrically connected. The integrated circuit includes a dummy transistor stacked vertically with the first pass gate transistor and including a gate electrode. The integrated circuit includes a butt contact electrically connected to the source/drain region of the first N-type transistor and the gate electrode of the dummy transistor and at least partially underlying or partially overlying the semiconductor nanostructures of the first pass gate transistor and at least partially overlying or underlying the source/drain region of the first N-type transistor.

In some embodiments, a method includes forming, in a first active region of an integrated circuit, a first inverter including a first N-type transistor stacked vertically with a first P-type transistor and forming, in a second active region of the integrated circuit, a second inverter cross-coupled with the first inverter and including a second N-type transistor stacked vertically with a second P-type transistor. The method includes forming, in the first active region, a first pass gate transistor stacked vertically with a first dummy transistor and forming a first butt contact in contact with a gate metal of the dummy transistor at the first active region and electrically connecting an output of the first inverter to an input of the second inverter. The gate metal of the first dummy transistor extends from the first active region to either the second N-type transistor or the second P-type transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first N-type transistor;
forming a second N-type transistor;
forming a first P-type transistor stacked vertically with the first N-type transistor;
forming a second P-type transistor stacked vertically with the second N-type transistor;
electrically coupling the first N-type transistor and the first P-type transistor as a first inverter by electrically shorting a gate terminal of the first N-type transistor with a gate terminal of the first P-type transistor;
electrically coupling the second N-type transistor and the second P-type transistor as a second inverter by electrically shorting a gate terminal of the second N-type transistor with a gate terminal of the second P-type transistor; and
forming a first butt contact electrically connecting an output of the first inverter to an input of the second inverter, wherein the first butt contact is at least partially within a first active region associated with the first inverter.

2. The method of claim 1, further comprising forming a first pass gate transistor and a first dummy transistor stacked vertically in the first active region.

3. The method of claim 1, further comprising forming a first gate metal extending unbroken between the first dummy transistor and either the second N-type transistor or the second P-type transistor, wherein the first butt contact contacts the first gate metal at least partially within the first active region, wherein the first butt contact and the first gate metal electrically connect the output of the first inverter to the input of the second inverter.

4. The method of claim 3, wherein the first N-type transistor, the first P-type transistor, the first pass gate transistor and the first dummy transistor each include a respective stack of channels.

5. The method of claim 4, wherein the channels of the dummy transistor are cut in a central region, wherein the first gate metal fills the central region.

6. The method of claim 3, wherein the first butt contact is positioned below both the first gate metal and the second gate metal.

7. The method of claim 3, wherein the first butt contact is positioned above both the first the metal and the second gate metal.

8. The method of claim 3, forming comprising forming a second butt contact electrically connecting an input of the first inverter to an output of the second inverter, wherein the second butt contact is at least partially within a second active region associated with the second inverter.

9. The method of claim 8, further comprising:
forming a second pass gate transistor and a second dummy transistor stacked vertically in the second active region; and
forming a second gate metal extending unbroken between the second dummy transistor and either the first N-type transistor or the first P-type transistor, wherein the second butt contact contacts the second gate metal at least partially within the second active region, wherein the second butt contact and the second gate metal electrically connect the output of the first inverter to the input of the second inverter, wherein the first and second inverters and the first and second pass gate transistors are an SRAM cell.

10. The method of claim 1, wherein the first butt contact is entirely within the first active region.

11. The method of claim 1, wherein the first butt contact overlaps an edge of the first active region.

12. A method, comprising:
forming a first N-type transistor including a first gate electrode and a plurality of stacked first channels;
forming a first P-type transistor stacked vertically with the first N-type transistor and including a gate electrode and a plurality of stacked second channels;
forming a first pass gate transistor including a gate electrode and a plurality of stacked third channels, wherein a source/drain region of the first pass gate transistor, a source/drain region of the first N-type transistor, and source/drain region of the first P-type transistor are all electrically connected;
forming a dummy transistor stacked vertically with the first pass gate transistor and including a gate electrode; and
forming a butt contact electrically connected to the source/drain region of the first N-type transistor and the gate electrode of the dummy transistor and at least partially underlying or partially overlying the channels of the first pass gate transistor and at least partially overlying or underlying the source/drain region of the first N-type transistor.

13. The method of claim 12, further comprising:
forming a second N-type transistor including a gate electrode and a plurality of stacked third channels; and
forming a second P-type transistor stacked vertically with the second N-type transistor and including a gate electrode and a plurality of stacked fourth channels, wherein the gate electrode of dummy transistor is integral with the gate electrode of the second P-type transistor.

14. The method of claim 13, further comprising:
forming a first inverter including the first N-type transistor and the first P-type transistor; and
forming a second inverter cross-coupled with the first inverter and including the second N-type transistor and the second P-type transistor.

15. The method of claim 13, wherein the first N-type transistor is above the first P-type transistor and the first pass gate transistor is above the first dummy transistor.

16. The method of claim 13, wherein the first P-type transistor is above the first N-type transistor and the first dummy transistor is above the first pass gate transistor.

17. The method of claim 13, wherein the gate electrode of the second N-type transistor, the gate electrode of the second P-type transistor, and the gate electrode of the dummy transistor collectively form an L shape.

18. An integrated circuit, comprising:
a first active region;
a first inverter in the first active region including a first N-type transistor stacked vertically with a first P-type transistor;
a second active region;
a second inverter in the first active region cross-coupled with the first inverter and including a second N-type transistor stacked vertically with a second P-type transistor;
a first pass gate transistor in the first active region stacked vertically with a first dummy transistor; and
a first butt contact in contact with a gate metal of the dummy transistor at the first active region and electrically connecting an output of the first inverter to an input of the second inverter, wherein the gate metal of the first dummy transistor extends from the first active region to either the second N-type transistor or the second P-type transistor.

19. The integrated circuit of 18, comprising a dielectric layer of the dummy transistor electrically isolating a gate metal of the pass gate transistor from the gate metal, wherein with dielectric layer vertically separates the gate metal of the first pass gate transistor from the gate metal of the first dummy transistor.

20. The integrated circuit of claim 18, wherein the butt contact is formed in back end processing of the integrated circuit.
